(19) United States
(12) Patent Application Publication
(10) Pub. No.: US 2008/0037228 A1
(43) Pub. Date: Feb. 14, 2008

(54) ELECTRONIC EQUIPMENT CABINET EXPANSION KIT WITH OFFSET BRACKETS

(75) Inventor: Richard Evans LEWIS II, Austin, TX (US)

Correspondence Address: TILLMAN WRIGHT, PLLC, PO BOX 471581, CHARLOTTE, NC, 28247, US

(73) Assignee: CHATSWORTH PRODUCTS, INC., Westlake Village, CA (US)

(21) Appl. No.: 11/837,538

(22) Filed: Aug. 12, 2007

Related U.S. Application Data
(60) Provisional application No. 60/822,234, filed on Aug. 12, 2006.
(60) Provisional application No. 60/938,702, filed on May 18, 2007.
(60) Provisional application No. 60/939,049, filed on May 19, 2007.

(51) Int. Cl. H05K 5/02

(52) U.S. Cl. 361/724

(57) ABSTRACT

An expanded electronic equipment cabinet includes a frame structure for supporting electronic equipment and a cabinet expansion kit that includes a panel and a plurality of offset brackets. The offset brackets are interposed between the frame support and panel to create space to accommodate accessories connected to the electronic equipment supported by the frame structure. Each offset bracket includes a frame attachment end to mount to the frame structure and an expansion attachment end having a first mounting element for mounting a first oversized panel on the frame structure and a second mounting element for mounting a second oversized panel on the frame structure such that the first and second oversized panels are held at right angles to each other. The offset bracket includes first and second arms, a curved spine, or any of a variety of alternative configurations.

### CROSS-REFERENCE TO RELATED APPLICATION

For purposes of the United States, the present application is a U.S. nonprovisional patent application of, and claims priority under 35 U.S.C. § 119(e) to, U.S. provisional patent application Ser. No. 60/822,234, filed Aug. 12, 2006, U.S. provisional patent application Ser. No. 60/938,702, filed May 18, 2007, and U.S. provisional patent application Ser. No. 60/939,049, filed May 19, 2007, each of which is incorporated by reference herein.

### COPYRIGHT STATEMENT

All of the material in this patent document is subject to copyright protection under the copyright laws of the United States and of other countries. The copyright owner has no objection to the facsimile reproduction by anyone of the patent document or the patent disclosure, as it appears in the Patent and Trademark Office patent file or records, but otherwise reserves all copyright rights whatsoever.

### BACKGROUND OF THE PRESENT INVENTION

1. Field of the Present Invention

The present invention relates generally to the field of cabinets for mounting and storing electronic components, and, more particularly, to expansion kits for expanding the available volume of a cabinet.

2. Background

Frames and cabinets for mounting and storing electronic components have been well known for many years. Frames are typically simple rectangular frameworks on which electronic components may be mounted, or on which other mounting members, such as shelves or brackets, may be mounted which in turn may support the electronic components. Cabinets are typically frames on which panels or doors, or both, are hung to provide aesthetic improvement, to protect the components from external influences, to provide security for the components stored inside, or for other reasons.

Frames and cabinets (sometimes collectively referred to hereinafter as “enclosures”) have been built in many different sizes and with many different proportions in order to best accommodate the components which they are designed to store. Large enclosures have been created to hold large components or to hold multiple components. Smaller enclosures are more commonly utilized for smaller components.

Components stored in these enclosures may include audio and video equipment and the like, but quite frequently include computer equipment and related peripheral devices. Regardless of the component type, each component typically requires an external power supply and a plurality of input and output cables, wires and the like (generally referred to hereinafter as “cables”). Some of these wires and cable are connected to other components in the same enclosure, and some of which extend out of the enclosure to either an adjacent enclosure or to a remote location, typically using either an overhead cabling system or an under-floor cabling system.

Apparatuses for routing cables and wires to and from that equipment are also well known. In particular, a wide variety of raceways are available for routing cables vertically through or adjacent to equipment enclosures. Such raceways may be used to route cables vertically to equipment mounted or otherwise supported in an enclosure from other equipment on the same enclosure, from an adjacent enclosure, from overhead or underfloor raceway, or the like. These cables are generally routed in the vertical direction to a point adjacent to the desired equipment and then routed in the horizontal direction to the desired equipment.

A particular problem inherent in the use of enclosures of all kinds is the issue of how to route and otherwise manage the large quantities of cables that are often necessary for a particular enclosure. Previously known enclosures utilize vertical cable raceways, ducts, and other enclosed or semi-enclosed structures to guide cables or bundles of cables upward and downward. Unfortunately, such structures provide very little flexibility in how cables or cable bundles are routed. Further, once cables or cable bundles are installed in such structures, it is relatively difficult to adjust the positions of the cables.

An additional problem is finding space within an enclosure to contain the large quantities of cables associated with the equipment being housed in the enclosure. Traditionally, enclosures are available in standard sizes, which are known and used throughout the enclosure industry. Further, control rooms are generally sized to contain and computer and electronic equipment generally fit within standard sized enclosures. Therefore, it is generally not realistically feasible to resize standard sized enclosures to accommodate cables. Accordingly, a standard sized enclosure that provides spacing to accommodate the large quantities of cables associated with electronic equipment stored therein is needed.

### SUMMARY OF THE PRESENT INVENTION

Broadly defined, the present invention according to one aspect is an offset bracket adapted to mount two oversized enclosure panels on a frame structure for supporting electronic equipment, including: a first portion having a first mounting element adapted to connect to the frame structure; and a second portion having a second mounting element adapted to connect to a first oversized enclosure panel and a third mounting element adapted to connect to a second oversized enclosure panel such that the first and second oversized enclosure panels are supported by the frame structure and held at right angles to each other.

In a feature of this aspect, the first mounting element includes a first planar element, having at least one aperture penetrating therethrough, that is adapted to abut a planar surface of the frame structure; the second mounting element includes a second planar element, having at least one aperture penetrating therethrough, that is parallel to the first planar element; and the third mounting element includes a third planar element, having at least one aperture penetrating therethrough, that is perpendicular to the first planar element.

In other features of this aspect, the first portion is a frame attachment end and the second portion is an expansion attachment end, and wherein the frame attachment end and the expansion attachment end are connected by a curved spine member; and the expansion attachment end is oriented at a right angle relative to the frame attachment end.

In other features of this aspect, the first portion is a first arm having opposing ends and a rectilinear form, and the second portion is a second arm, having opposing ends and a rectilinear form, that is fixedly connected at one end to the first arm such that the second arm forms an angle relative to the first arm; and the angle formed between the first and second arms is a right angle.

In other features of this aspect, the second portion is an arm, and the second mounting element includes a planar flange extending from the end of the arm; and the first mounting element includes a first planar element and the planar flange extends at a right angle from the end of the arm and is perpendicular to the first planar element.

Broadly defined, the present invention according to another aspect is an offset bracket adapted to support an oversized enclosure panel at a laterally-displaced distance from a frame structure for supporting electronic equipment, including: a frame attachment end having a first mounting element adapted to connect to the frame structure, the first mounting element including a first planar element, having at least one aperture penetrating therethrough, that is adapted to abut a planar surface of the frame structure; a curved spine member adapted to extend laterally away from the frame structure when the frame attachment end is connected to the frame structure; and an expansion attachment end having a second mounting element for mounting the oversized enclosure panel thereon such that the panel is supported at a laterally-displaced distance from the frame structure, wherein the second mounting element includes a second planar element, having at least one aperture penetrating therethrough, that is perpendicular to the first planar element.

In features of this aspect, the second mounting element is a planar flange extending from the end of the expansion attachment end; and the planar flange extends at a right angle from the expansion attachment end of the offset bracket and is perpendicular to the first planar element.

In other features of this aspect, the curvature of the curved spine member occurs within a horizontal plane; and/or the curvature of the curved spine member is generally uniform.

Broadly defined, the present invention according to another aspect is an offset bracket adapted to support an oversized enclosure panel at a laterally-displaced distance from a frame structure for supporting electronic equipment, including: a first arm having proximal and distal ends and a rectilinear form, the first arm adapted to connect at the proximal end to the frame structure; and a second arm having proximal and distal ends and a rectilinear form, wherein the proximal end of the second arm is fixedly connected to the distal end of the first arm such that the second arm forms an angle relative to the first arm, and wherein the distal end of the second arm is adapted for mounting the oversized enclosure panel thereon such that the panel is supported at a laterally-displaced distance from, and at right angles to, the frame structure.

In a feature of this aspect, the angle formed between the first and second arms is a right angle.

In another feature of this aspect, the first and second arms are oriented at right angles to the frame structure.

In other features of this aspect, the proximal end of the first arm includes a first mounting element adapted to connect to the frame structure, and the distal end of the second arm includes a second mounting element for mounting the oversized enclosure panel thereon such that the panel is supported at a laterally-displaced distance from the frame structure; the first mounting element includes a first planar element, and the second mounting element includes a planar flange extending from the end of the second arm; and the planar flange extends at a right angle from the end of the second arm and is perpendicular to the first planar element.

In another feature of this aspect, the first mounting element includes a first planar element, having at least one aperture penetrating therethrough, that is adapted to abut a planar surface of the frame structure, and the second mounting element includes a second planar element, having at least one aperture penetrating therethrough, that is perpendicular to the first planar element.

Broadly defined, the present invention according to another aspect is an expanded electronic equipment cabinet, including: a frame structure for supporting electronic equipment; and a cabinet expansion kit, having a panel and a plurality of offset brackets; wherein a first end of each offset bracket of the plurality of offset brackets is connected to, and extends laterally from, the frame structure and wherein the panel is connected to a second end of each offset bracket of the plurality of offset brackets such that the panel is supported by the offset brackets at a laterally-displaced distance from, and at right angles to, the frame structure.

In features of this aspect, the panel is a first panel and the cabinet expansion kit further includes a second panel that is connected to the second end of each offset bracket of the plurality of offset brackets such that the second panel is supported by the offset brackets at a laterally-displaced distance from, and at right angles to, the frame structure; and the first and second panels are a door and a side panel, respectively, that are arranged at right angles to each other.

In another feature of this aspect, a space is created between the panel and the frame structure to accommodate accessories connected to the electronic equipment supported by the frame structure.

In another feature of this aspect, each offset bracket includes a curved spine extending laterally away from the frame structure.

In alternative features, each offset bracket includes first and second arms, each having proximal and distal ends and a rectilinear form, wherein the proximal end of the second arm is fixedly connected to the distal end of the first arm such that the second arm forms an angle relative to the first arm; the angle formed between the first and second arms is a right angle; and the first and second arms are oriented at right angles to the frame structure.

In other features of this aspect, the frame structure includes at least four vertical members, each having at least two of the plurality of offset brackets attached thereto and extending laterally therefrom, and the cabinet expansion kit includes at least four panels, each of which is supported at each of its four corners by an offset bracket; the at least four panels are each displaced an equal distance from the frame structure; a first of the at least four panels is a front panel, a second of the at least four panels is a rear panel, a third of the at least four panels is a left side panel, and a fourth of the at least four panels is a right side panel, wherein the front and rear panels are displaced a first distance from the frame structure and the left and right side panels are displaced a second distance from the frame structure, and the first and second distances are unequal; each of the at least four panels has a respective width, each of the at least four panels is adjacent a respective pair of vertical members, and at least two of the at least four panels are oversized panels that are each wider than the distance between the two vertical members of the pair of vertical members to which the respective panel is adjacent; and alternatively, four of the at least four panels are oversized panels that are each wider than the distance between the two vertical members of the pair of vertical members to which the respective panel is adjacent.

In other features of this aspect, the cabinet further includes a top panel extension that extends laterally and outwardly from a top of the frame structure by an amount equal to the laterally-displaced distance; the cabinet further includes a top panel disposed on the top of the frame structure, and the top panel extension fits around the top panel; and one or more cable openings are arranged in the top panel extension.

In another feature of this aspect, the second end of each offset bracket includes a planar flange extending therefrom.

In another feature of this aspect, the first end has a first mounting element adapted to connect to the frame structure, the first mounting element including a first planar element, having at least one aperture penetrating therethrough, that is adapted to abut a planar surface of the frame structure, and the second end has a second mounting element for mounting the panel thereon such that the panel is supported at a laterally-displaced distance from the frame structure, wherein the second mounting element includes a second planar element, having at least one aperture penetrating therethrough, that is perpendicular to the first planar element.

Broadly defined, the present invention according to another aspect is a method of expanding an electronic equipment cabinet having a frame structure for supporting electronic equipment, including: providing a first enclosure for supporting electronic equipment, the first enclosure including at least one panel mounted on a frame structure formed from a plurality of frame members, including a plurality of vertical members; removing a first panel, of the at least one panel, from a face of the frame structure; attaching a plurality of offset brackets to vertical members of the frame structure, each offset bracket extending laterally from the frame structure and including a mounting element for supporting a panel; and attaching a second panel to the mounting element on the offset bracket, thereby creating a second enclosure formed from the frame structure and the second panel; wherein additional space is enclosed within the second enclosure, between the second panel and the frame structure, as compared to the space enclosed within the first enclosure.

In a feature of this aspect, the first and second panels are the same width.

In another feature of this aspect, the first and second panels are different panels and wherein the second panel is wider than the first panel.

In another feature of this aspect, each offset bracket includes first and second arms, each having proximal and distal ends and a rectilinear form, wherein the proximal end of the second arm is fixedly connected to the distal end of the first arm such that the second arm forms a right angle relative to the first arm. Alternatively, each offset bracket includes a curved spine member.

Broadly defined, the present invention according to another aspect is a method of expanding an electronic equipment cabinet having a frame structure for supporting electronic equipment, including: providing a first enclosure for supporting electronic equipment, the first enclosure including a first front panel, a first left side panel, a first rear panel and a first right side panel, all mounted on a frame structure formed from a plurality of frame members, including four vertical post members; removing the first front, left side, rear and right side panels from the frame structure; attaching an offset bracket to each of the four vertical post members of the frame structure, each offset bracket extending laterally from the frame structure and including at least two mounting elements, each mounting element for supporting a panel; a second front panel to a mounting element on a first offset bracket, a second left side panel to a mounting element on the first offset bracket and to a mounting element on a second offset bracket, a second rear panel to a mounting element on the second offset bracket and to a mounting element on a third offset bracket, a second right side panel to a mounting element on the third offset bracket and to a mounting element on a fourth offset bracket, and the second front panel to a mounting element on the fourth offset bracket, thereby creating a second enclosure formed from the frame structure and the second front, left side, rear and right side panels; wherein additional space is enclosed within the second enclosure, between the second front, left side, rear and right side panels and the frame structure, as compared to the space enclosed within the first enclosure.

In a feature of this aspect, each offset bracket includes first and second arms, each having proximal and distal ends and a rectilinear form, wherein the proximal end of the second arm is fixedly connected to the distal end of the first arm such that the second arm forms a right angle relative to the first arm. Alternatively, each offset bracket includes a curved spine member.

### BRIEF DESCRIPTION OF THE DRAWINGS

Further aspects, features, embodiments, and advantages of the present invention will become apparent from the following detailed description with reference to the drawings, wherein:

FIG. 1A is a shaded orthogonal view of the top and left side of an expanded electronic equipment cabinet in accordance with a preferred embodiment of the present invention;

FIG. 1B is an orthogonal view of top and right side of the cabinet of FIG. 1A;

FIG. 1C is a shaded orthogonal view of the bottom and left side of the cabinet of FIG. 1A;

FIG. 1D is a shaded orthogonal view of the rear of the cabinet of FIG. 1A;

FIG. 1E is a shaded orthogonal view of the bottom of the cabinet of FIG. 1A;

FIG. 2 is an orthogonal view of one of the offset brackets of FIG. 1A;

FIG. 3 is an exploded orthogonal view of the cabinet of FIG. 1B.

FIG. 4A is a shaded orthogonal view of the front, top, and right side of an alternative embodiment of an expanded electronic equipment cabinet in accordance with a preferred embodiment of the present invention;

FIG. 4B is a shaded orthogonal view of the cabinet of FIG. 4A with a side panel removed;

FIG. 5 is an orthogonal view of the four post frame structure of FIG. 4B; and

FIG. 6 is a view of one of the offset brackets of FIG. 5.

### DETAILED DESCRIPTION OF THE PREFERRED EMBODIMENTS

As a preliminary matter, it will readily be understood by one having ordinary skill in the relevant art (“Ordinary Artisan”) that the present invention has broad utility and application. Furthermore, any embodiment discussed and identified as being “preferred” is considered to be part of a best mode contemplated for carrying out the present invention. Other embodiments also may be discussed for additional illustrative purposes in providing a full and enabling disclosure of the present invention. Moreover, many embodiments, such as adaptations, variations, modifications, and equivalent arrangements, will be implicitly disclosed by the embodiments described herein and fall within the scope of the present invention.

Accordingly, while the present invention is described herein in detail in relation to one or more embodiments, it is to be understood that this disclosure is illustrative and exemplary of the present invention, and is made merely for the purposes of providing a full and enabling disclosure of the present invention. The detailed disclosure herein of one or more embodiments is not intended, nor is to be construed, to limit the scope of patent protection afforded the present invention, which scope is to be defined by the claims and the equivalents thereof. It is not intended that the scope of patent protection afforded the present invention be defined by reading into any claim a limitation found herein that does not explicitly appear in the claim itself.

Thus, for example, any sequence(s) and/or temporal order of steps of various processes or methods that are described herein are illustrative and not restrictive. Accordingly, it should be understood that, although steps of various processes or methods may be shown and described as being in a sequence or temporal order, the steps of any such processes or methods are not limited to being carried out in any particular sequence or order, absent an indication otherwise. Indeed, the steps in such processes or methods generally may be carried out in various different sequences and orders while still falling within the scope of the present invention. Accordingly, it is intended that the scope of patent protection afforded the present invention is to be defined by the appended claims rather than the description set forth herein.

Additionally, it is important to note that each term used herein refers to that which the Ordinary Artisan would understand such term to mean based on the contextual use of such term herein. To the extent that the meaning of a term used herein-as understood by the Ordinary Artisan based on the contextual use of such term-differs in any way from any particular dictionary definition of such term, it is intended that the meaning of the term as understood by the Ordinary Artisan should prevail.

Furthermore, it is important to note that, as used herein, “a” and “an” each generally denotes “at least one,” but does not exclude a plurality unless the contextual use dictates otherwise. Thus, reference to “a picnic basket having an apple” describes “a picnic basket having at least one apple” as well as “a picnic basket having apples.” In contrast, reference to “a picnic basket having a single apple” describes “a picnic basket having only one apple.”

When used herein to join a list of items, “or” denotes “at least one of the items,” but does not exclude a plurality of items of the list. Thus, reference to “a picnic basket having cheese or crackers” describes “a picnic basket having cheese without crackers”, “a picnic basket having crackers without cheese”, and “a picnic basket having both cheese and crackers.” Finally, when used herein to join a list of items, “and” denotes “all of the items of the list.” Thus, reference to “a picnic basket having cheese and crackers” describes “a picnic basket having cheese, wherein the picnic basket further has crackers,” as well as describes “a picnic basket having crackers, wherein the picnic basket further has cheese.”

Referring now to the drawings, in which like numerals represent like components throughout the several views, the preferred embodiments of the present invention are next described. The following description of the preferred embodiment(s) is merely exemplary in nature and is in no way intended to limit the invention, its application, or uses.

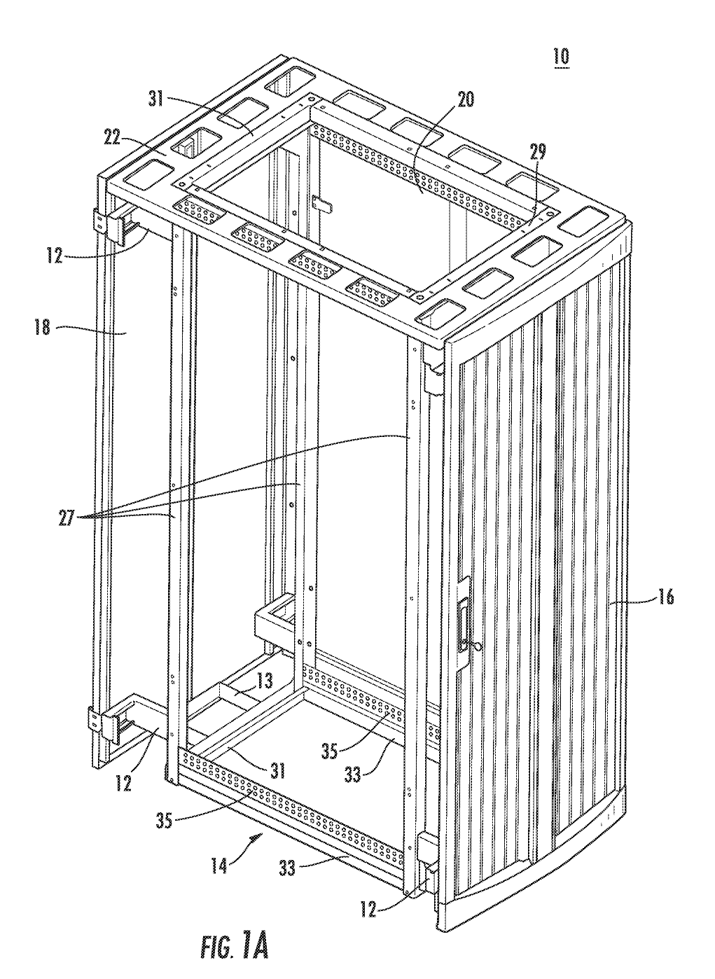

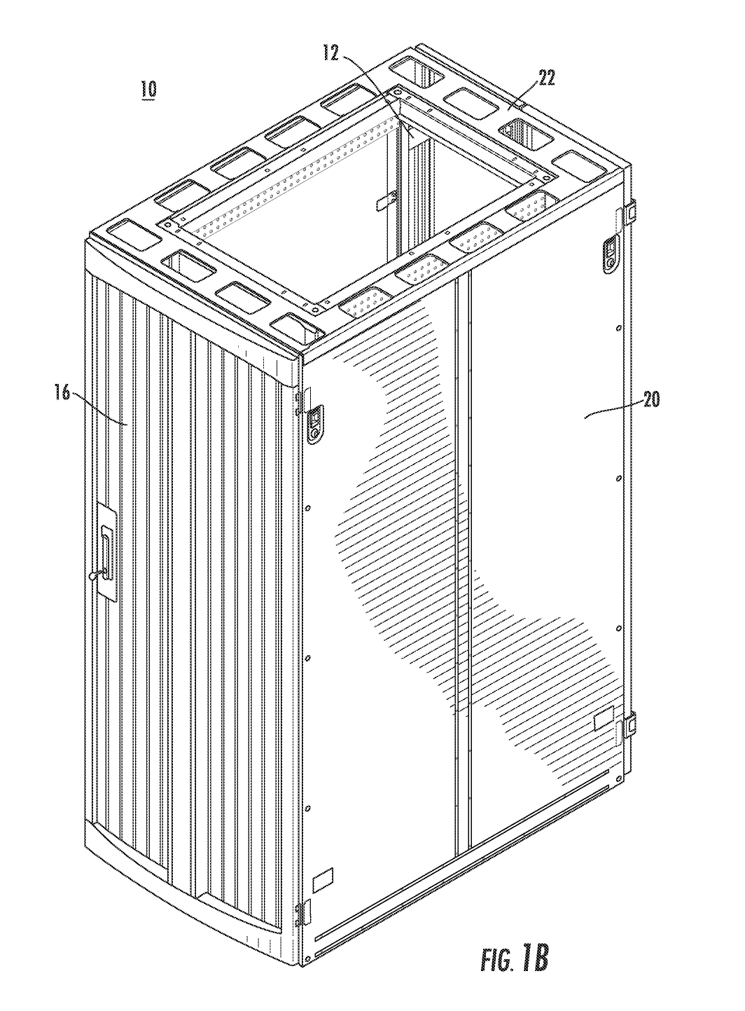

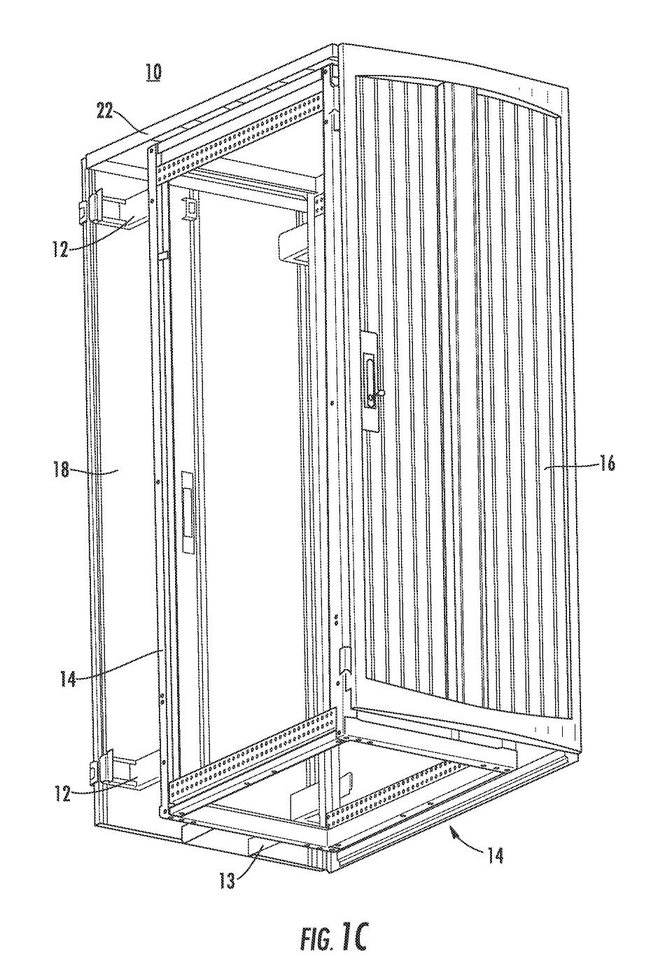

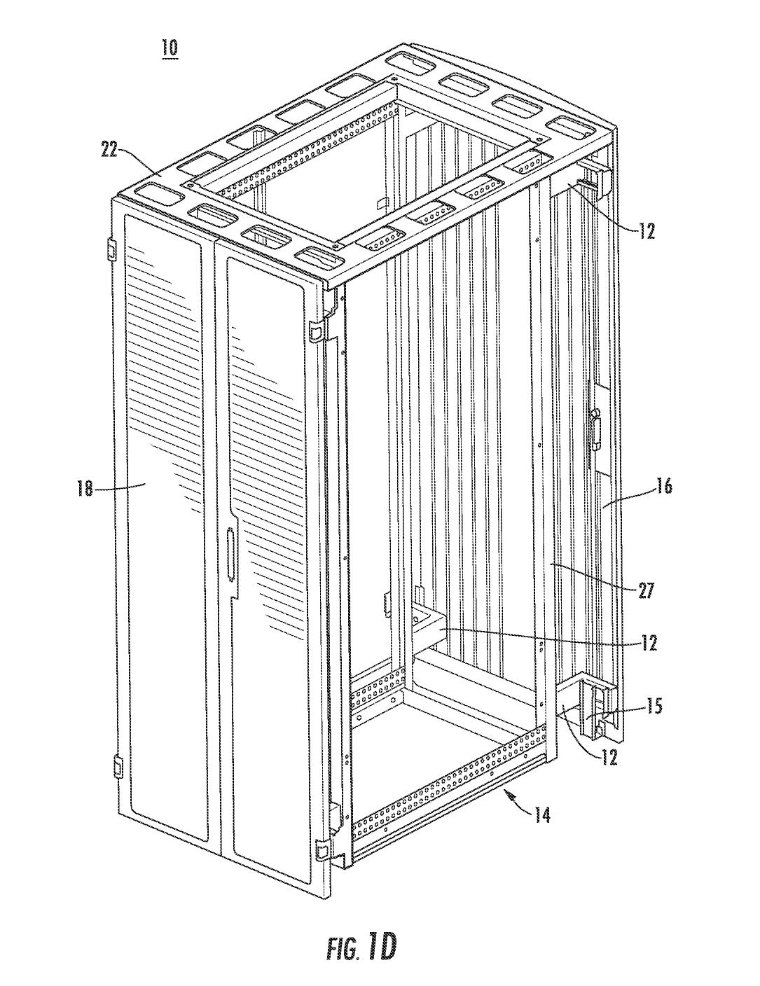

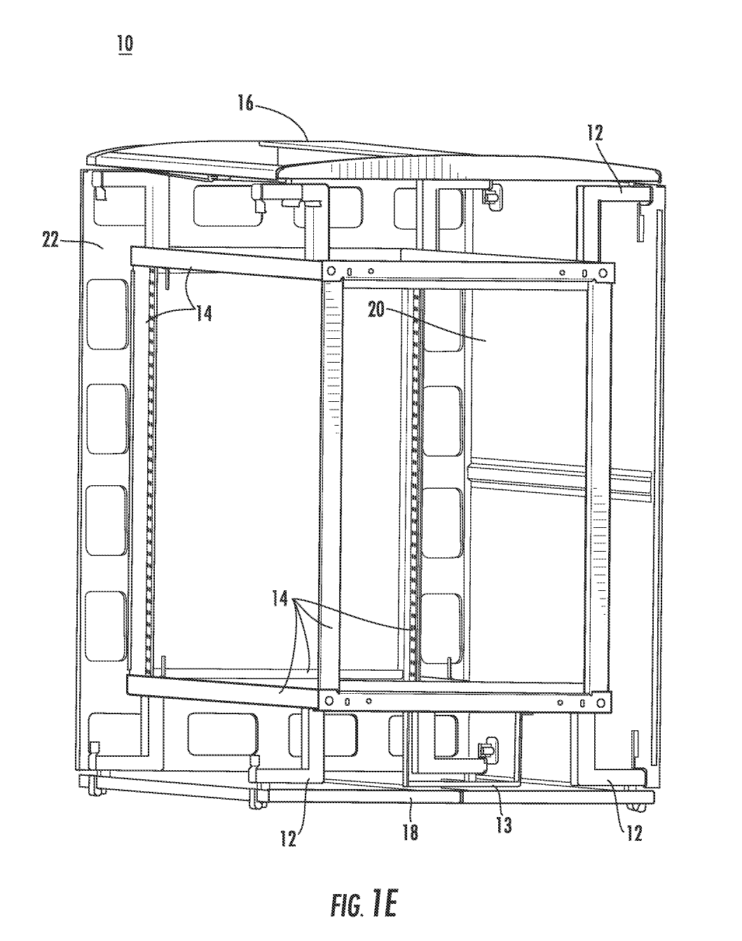

FIGS. 1A-1E are various orthogonal views of an expanded electronic equipment cabinet 10 in accordance with a preferred embodiment of the present invention. As shown therein, the expanded cabinet 10 includes an interior four post frame structure 14 and a cabinet expansion kit, wherein the cabinet expansion kit may include a plurality of offset brackets 12, one or more center support brackets 13, an oversized front door 16, an oversized back panel 18 and a top panel extension 22. As also shown, the cabinet expansion kit may also include an oversized side panel 20 on either the left side or the right side of the cabinet 10, but it will be recognized that in alternative embodiments a second side panel 20 may likewise be included, on the opposite side of the first, or the side panels may be omitted altogether. The purpose of the various implementations is discussed elsewhere hereinbelow.

In the illustrated embodiment, the back panel 18 is actually a pair of hinged doors. In this regard, it will be apparent that various replacement components may be substituted for the components of the expansion kit, without departing from the scope of the present invention, so long as the general approach of expanding the interior volume of a four post frame structure with some sort of brackets is utilized.

The interior four post frame structure 14 may be of conventional design and construction, and in fact the present invention is perhaps most applicable to, and useful with, conventional four post frame structures. As shown and described, the four post frame structure 14 is formed from a plurality of frame members including four vertical members 27, upper and lower front cross members 29, upper and lower rear cross members 31 and two pairs of upper and lower side cross members 33. Each vertical member 27 includes a plurality of cross member attachment apertures at each end. Two of the vertical members 27 are connected together at their upper and lower ends by the upper and lower front cross members 29, respectively, and the other two vertical members 27 are connected together at their upper and lower ends by the upper and lower rear cross members 31, respectively. The front cross members 29 and their respective vertical members 27 thus define a front frame, and the rear cross members 31 and their respective vertical members 27 define a rear frame. The front and rear frames may then be connected together at their respective corners by the upper and lower side cross members 33.

Any known connection means may be used to join the various members together. Although not illustrated herein, at least one example of conventional connection means is described in commonly-assigned U.S. Pat. No. 6,185,098, the entirety of which is incorporated herein by reference. Although likewise not illustrated herein, the precision and the stability of each of the corners of at least some types of four post frame structures may be enhanced by utilizing a self-squaring corner attachment bracket such as that disclosed by the commonly-assigned U.S. Pat. No. 5,997,117 entitled “RACK FRAME CABINET,” the entirety of which is hereby incorporated by reference.

The four post frame structure 14 may further comprise four horizontal mounting rails 35. Each horizontal mounting rail 35 includes two rows of mounting apertures extending along its entire length. Optionally, vertical mounting rails (not shown) may be mounted to the horizontal mounting rails 35. Each vertical mounting rail preferably includes a series of evenly-spaced, threaded mounting apertures, extending along substantially its entire length, for use in mounting electronic components, peripheral devices, cable brackets, additional mounting members, or the like thereto.

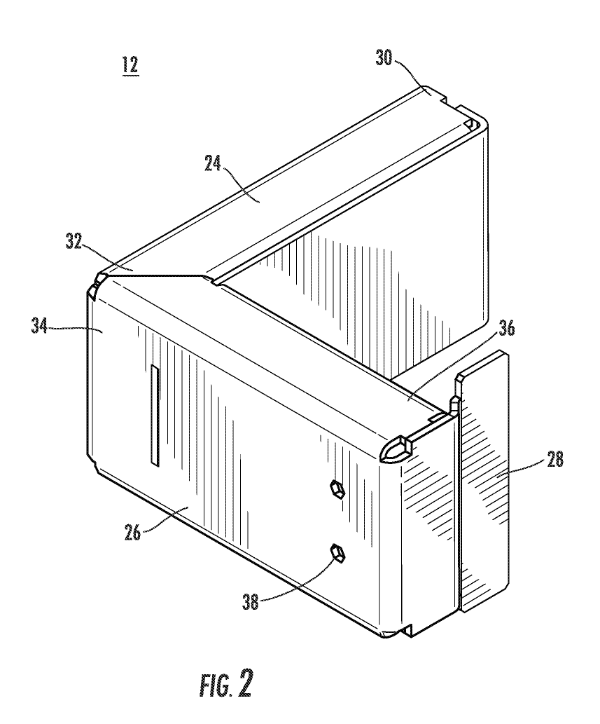

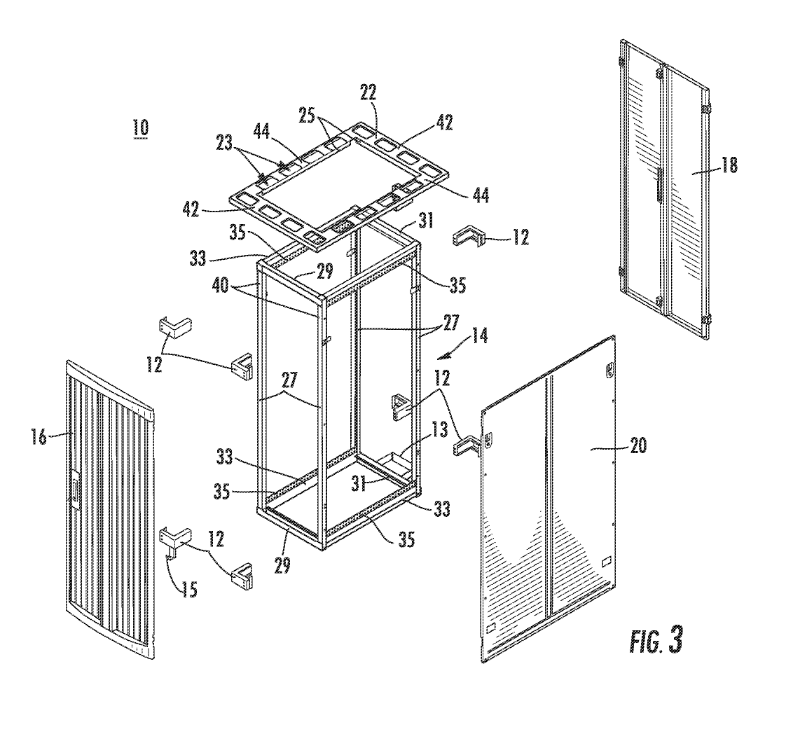

FIG. 2 is an orthogonal view of one of the offset brackets of FIG. 1A. The bracket 12 includes a first arm 24, a second arm 26 and a side panel mounting element 28. The first and second arms 24,26 each include a proximal end 30,34 and a distal end 32,36. A mounting surface, not shown in FIG. 2 but visible on some of the offset brackets 12 illustrated in FIG. 3, is located at the proximal end 30 of the first arm 24 and includes a plurality of mounting apertures penetrating therethrough. The distal end 32 of the first arm 24 is fixedly connected to a proximal end 34 of the second arm 26, with the arms 24,26 preferably being connected at a 90 degree angle relative to one another, i.e., the first arm 24 and second arm 26 connect to form an L-shaped bracket. The side panel mounting element 28, which in at least some embodiments is a generally planar plate-like structure, is fixedly connected to the distal end 36 of the second arm 26. An additional pair of mounting holes 38 are disposed adjacent the distal end 36 of the second arm 26. Such holes 38 may be used to mount hinges, bumpers, a door strike, a latch point and the like.

In use, each offset bracket 12 may be mounted to the front- or rear-facing surface of a vertical member 27, as appropriate, such that it extends outwardly, away from the interior frame structure 14. Each offset bracket 12 may be attached to its respective vertical member 27 using the apertures in the mounting surface located at the proximal end 30 of the first arm 24. Each offset bracket 12 is arranged so that its second arm 26 is oriented to point outwardly from the side of the interior frame structure 14 as shown in FIGS. 1A-1E. As illustrated therein, a first offset bracket 12 is disposed near the top of each vertical member 27 and a second offset bracket 12 is disposed near the bottom of each vertical member 27. Each lateral side or face of the interior frame structure 14 (front, left side, rear, right side) thus has four mounting points for mounting a respective panel.

The offset brackets 12 provide versatility for a traditional frame structure by providing a means to support the various front, rear and side panels 16,18,20 away from the frame structure 14. Because the various panels 16,18,20 are thus located farther away from the equipment mounted in the interior of the frame structure 14 than panels mounted directly to the frame structure 14 would be, additional space is thus provided for cables, internal ducts, or other accessories. More particularly, the offset brackets 12 and center support bracket 13 adapt a conventional frame structure 14 to hold larger doors and side panels than could be accommodated by the interior frame structure 14 by itself, thereby increasing the area available for cable management and/or thermal management in the side space and front and back space of a data center cabinet while creating minimal impediment to cables entering through a raised floor tile or cabinet top panel.

In order to provide greater support for any of the panels 16,18,20, and particularly to provide a door stop for the free ends of a pair of doors such as the pair of doors comprising the rear panel 18 in the illustrated embodiment, a center support bracket 13 may be provided at the top or bottom of the front, rear, left or right side of the interior frame structure 14. As perhaps best illustrated in FIG. 1E, such a center support bracket 13 may include two extension arms connected at their distal ends by a single cross arm. Each extension arm is attached to the lower rear cross member 31 using a respective mounting tab. Such a structure may be formed by bending or angling a single member along four lines to produce the extension arms, cross arm, and mounting tabs.

For a panel comprising a single door, such as the front door 16 illustrated herein, one of the offset brackets 12 may be modified by applying an additional door stop arm 15 thereto. As perhaps best shown in FIG. 1D, the door stop arm 15 includes an L-shaped arm mounted to the second arm 26 of the selected offset bracket 12. At the distal end of the L-shaped arm is a flange arranged to contact the bottom corner of the front door 16 when the door is swung closed against the rest of the cabinet 10. Although not illustrated, a door stop arm 15 may likewise be attached to the offset bracket 12 disposed at the upper corner of the front door 16 to provide similar functionality with regard to the top corner of the door 16.

FIG. 3 is an exploded orthogonal view of the cabinet of FIG. 1B, more particularly illustrating the use of the offset brackets 12. As shown therein, the offset brackets are mounted to the interior frame structure 14 using apertures 40 in the various members of the frame structure 14. If the interior frame structure 14 is to be produced in conjunction with the cabinet expansion kit, then the apertures 40 may be created in any desired location. However, in many cases, the cabinet expansion kit will be retrofitted to an existing interior frame structure 14. In this case, the offset brackets 12 may be installed in preexisting mounting apertures 40 found in the vertical members 27 of most conventional interior frame structures 14. These apertures 40 are often normally used to mount hinges and other support hardware for doors or other panels, or in some cases are used to support equipment in the frame structure 14. Typically, these apertures 40 are located generally near a top and a bottom of the vertical members 27 so as to provide sufficient stability for the doors, panels or other apparatuses mounted thereon while still providing ready access thereto.

The various components of the cabinet expansion kit may be connected to the interior frame structure 14 as follows. First, the offset brackets 12 may be mounted by connecting the proximal end 30 of the first arm 24 of each offset bracket 12 to the set of apertures 40 of the frame structure 14 using any known fasteners of suitable size and construction. As described previously, each offset bracket 12 is installed so that it extends outwardly from the front or rear of the interior frame structure 14, as appropriate, and so that the bottom of the L-shape (i.e., the second arm 26) is oriented to extend outwardly from the respective side of the interior frame structure 14. In this arrangement, the mounting holes 38 in each offset bracket 12 are oriented to face in the same direction as the mounting apertures 40 to which the offset bracket 12 itself is mounted, but are shifted forward or rearward, as appropriate, and to the side, relative to the mounting apertures 40. In this sense, because the mounting holes 38 in the offset bracket 12 are often intended to serve the same purpose as the mounting apertures 40 (supporting panels, and particularly, providing an attachment point for a hinge used to support a door panel), the mounting holes 38 may be said to be “offset” from the original mounting apertures 40.

With the offset brackets 12 in place, the displaced hinges, and therefore oversized front and rear door panels 16,18, may be attached to the mounting holes 38 of the offset brackets 12. Further, oversized side panels 20 may be attached to the side panel mounting elements 28 of the offset brackets 12. Any suitable mounting or attachment means may be used to provide these various connections. Optionally, additional mounting apertures (not shown) may be provided in the side panel mounting elements 28 or elsewhere in the second arm 26 of each offset bracket 12 in order to facilitate such connections.

As shown, an oversized front door 16, an oversized back panel 18 and one oversized side panel 20 are used in association with the offset brackets 12 of the invention. As will be apparent to the Ordinary Artisan, a variety of panels may be substituted for each of the doors and other panels, or omitted entirely in some applications. For example, the single side panel 20 shown in the drawings may be omitted entirely if the cabinet 10 is intended to be used as a middle one of a row of cabinets lined up side by side. The illustrated cabinet 10 (i.e., a cabinet 10 with only a single side panel 20) may be appropriate for the end cabinet in a row of cabinets. For a standalone cabinet, or to provide increased security or to improve the appearance of a cabinet, a second side panel 20, identical in design and construction to the first (or in some embodiments, the mirror image of the first), may be installed on the opposite side. Likewise, doors may be included on the front, rear, both the front and the rear or neither the front nor the rear of the cabinet 10, all as desired for the particular application. Solid panels useful for covering the front or rear will be known to the Ordinary Artisan. One type of door may also be replaced by another; for example, the single front door 16 illustrated herein may be replaced by the two-door door panel 18 shown at the rear of the cabinet 10, and vice versa. Preferably, a wide variety of interchangeable doors and panels may be made available as options to provide the user with a substantial degree of flexibility in selecting the doors and other panels to be used with the expanded electronic equipment cabinet 10.

Additional flexibility may be provided with regard to the top of the cabinet 10. Although not shown, conventional enclosures, such as are conventionally used with the interior frame structure 14 illustrated herein, commonly include a top panel covering a substantial portion of the top of the frame structure 14. Such top panels typically include openings for venting hot air from the interior of the frame structure 14, for routing cables from the interior of the frame structure 14 through the top to overhead cable raceways or the like located above, or for both.

To complement such existing top panels, the cabinet expansion kit of the present invention includes a top panel extension 22 that fits around the existing top panel to fully cover the top of the expanded cabinet 10. The top panel extension 22 itself is perhaps best seen in FIG. 3 and comprises a generally planar frame sized to fit around the outside of the interior frame structure 14. The frame of the extension 22 is formed from two end members 42 and two side members 44, each of which includes a plurality of generally evenly-spaced cable openings 23 and a mounting flange 25 to facilitate connection of the extension 22 to the frame structure 14. The dimensions of the extension 22 are selected to correspond to the size of the offset brackets 12. More specifically, the end members 42 for the ends of the top panel extension 22 that extend to the front door 16 and the back panel 18 are substantially the same width as the first arm 24 of each offset bracket 12, and the side members 44 for the sides of the top panel extension 22 that extend to the side panels 20 are substantially the same width as the second arm 26 of each offset bracket 12. These widths allow the top panel extension 22 to fit neatly adjacent the oversized door 16, back panel 18 and side panel 20.

Alternatively, an existing top panel may be removed entirely and replaced with an integrated top panel (not shown) that includes the functionality of both the existing top panel and the top panel extension 22 described and illustrated herein, or with any other functionality desired.

In use, the expanded cabinet 10 provides substantially more space for cables and cable routing apparatuses than were possible in the interior frame structure 14 by itself. With the cabinet expansion kit in place, cables may be routed outside the boundaries of the original frame structure 14 in the space created by expanding the front, rear and sides of the cabinet. Conventional cable routing structures, such as raceways and the like, may be used to assist this process. In at least some embodiments, existing cable routing structures may be utilized, while in others, new cable routing structures may be developed. Also, cables may be routed through the top panel extension 22 using the cable openings 23, using any cable openings that may exist in the existing top panel, or both.

Advantageously, use of the cabinet expansion kit permits a user to expand the volume of a frame structure 14 without having to replace the various members 27,29,31,33 of the frame structure 14, thus providing considerable cost savings. Expanding an existing frame structure 14, rather than replacing it, may also result in considerable labor savings, because electronic equipment mounted therein, and some or all of the cables connected to such equipment, may not need to be moved during the expansion process, and thus the frame structure 14 may be expanded without disturbing the installation therein.

In another advantage of the present invention, the offset brackets 12 and the various doors and other panels 16,18,20,22 may be dimensioned so as to form an expanded cabinet 10 that is the same in one or more dimensions as a larger frame structure (not shown). In other words, frame structures 14 of different sizes could be provided such that installing a cabinet expansion kit on a smaller frame structure 14 could produce an enclosure that is the same size as the larger frame structure. In conjunction with this approach, various doors and other panels 16,18,20 could be designed to mount either on the smaller frame structure 14, via the offset brackets 12, or on the larger frame structure (not shown) via direction connection. A product line built around this approach could provide even greater flexibility to users by offering multiple upgrade options to the user.

Further, alternate cabinet configurations could allow for the space added by the offset brackets to be asymmetrically biased. In other words, the additional volume created by the offset brackets 12 may be added more to the front or rear of the cabinet 10 and/or more to one side of the cabinet 10 or the other by adding offset brackets (not shown) with unequal first or second arm lengths, as appropriate. Such an embodiment would provide flexibility and customizability. For example, offset brackets of varying lengths could be used in a situation wherein large cable access requirements are only present on the frontward or rearward face of the equipment. Of course, to achieve such an arrangement, the same front, rear and side panels could be utilized, but different offset brackets and a different top panel or top panel extension may be required.

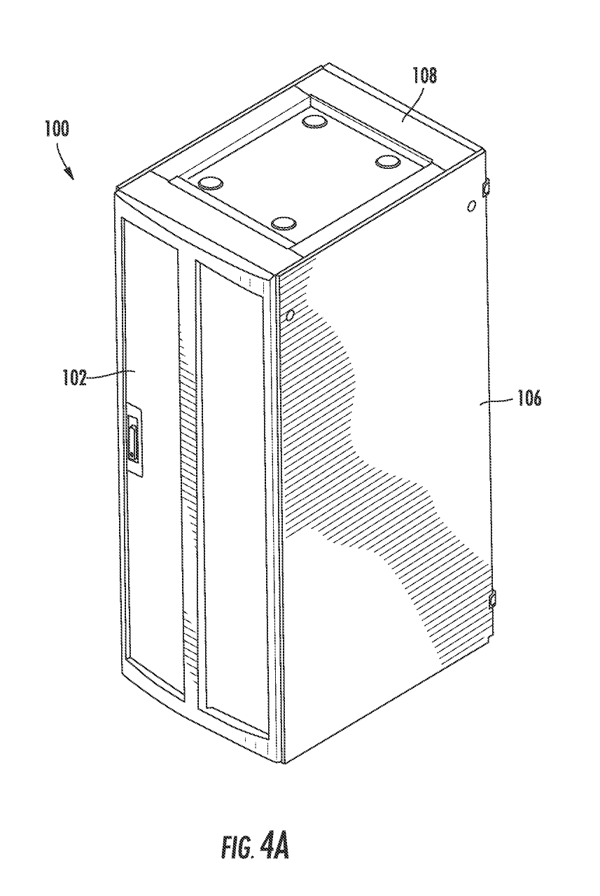

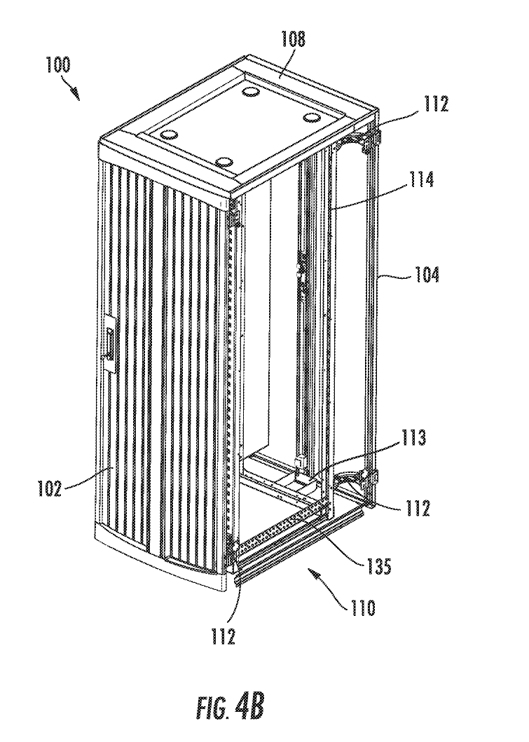

FIGS. 4A-4B are various orthogonal views of an expanded electronic equipment cabinet 100 in accordance with another preferred embodiment of the present invention. The expanded electronic equipment cabinet 100 in FIG. 4A is shown fully enclosed, while in FIG. 4B, a side panel 106 has been removed to better show an interior of the cabinet 100. The expanded cabinet 100 includes an interior four post frame structure 110 and a cabinet expansion kit, wherein the cabinet expansion kit may include a plurality of offset brackets 112, one or more center support brackets 113, an oversized front door 102, an oversized back panel 104, a pair of oversized side panels 106 and a top extension panel 108.

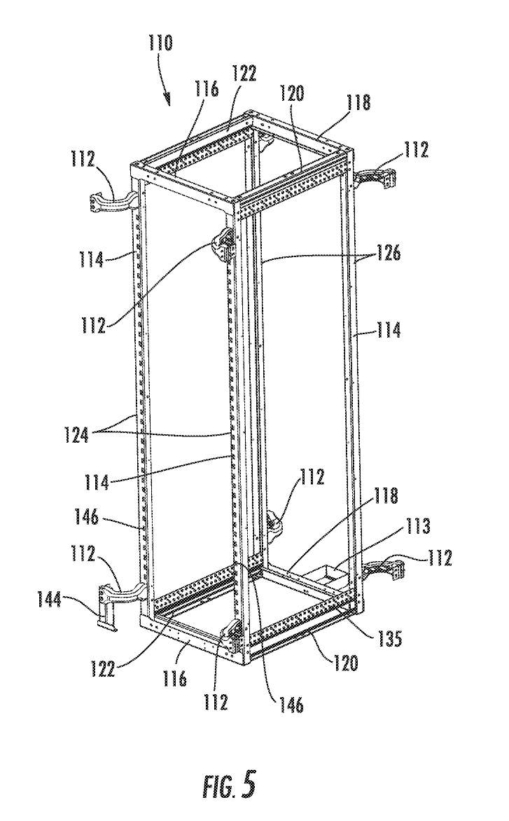

With particular reference to the four post frame structure 110, FIG. 5 is a perspective view of the four post frame structure 110. The four post frame structure 110 may be of conventional design and construction, and in fact the present invention is perhaps most applicable to, and useful with, conventional four post frame structures. As shown and described, the four post frame structure 110 includes four vertical members 114, upper and lower front cross members 116, upper and lower rear cross members 118 and two pairs of upper and lower side cross members 120,122. Each vertical member 114 includes a plurality of cross member attachment apertures at each end. Two of the vertical members 114 are connected together at their upper and lower ends by the upper and lower front cross members 116, respectively, and the other two vertical members 114 are connected together at their upper and lower ends by the upper and lower rear cross members 118, respectively. The front cross members 116 and their respective vertical members 114 thus define a front frame 124, and the rear cross members 118 and their respective vertical members 114 define a rear frame 126. The front and rear frames 124,126 may then be connected together at their respective s by the upper and lower side cross members 120,122.

Any known connection means may be used to join the various members together. Although not illustrated herein, at least one example of conventional connection means is described in the aforementioned U.S. Pat. No. 6,185,098. Although likewise not illustrated herein, the precision and the stability of each of the s of at least some types of four post frame structures may be enhanced by utilizing a self-squaring corner attachment bracket such as that disclosed by the aforementioned U.S. Pat. No. 5,997,117.

Though not shown in FIGS. 4A, 4B or 5, the four post frame structure 110 may further comprise four horizontal mounting rails 135. Each horizontal mounting rail 135 includes two rows of mounting apertures extending along its entire length. Optionally, vertical mounting rails (not shown) may be mounted to the horizontal mounting rails 135. Each vertical mounting rail preferably includes a series of evenly-spaced, threaded mounting apertures, extending along substantially its entire length, for use in mounting electronic components, peripheral devices, cable brackets, additional mounting members, or the like thereto.

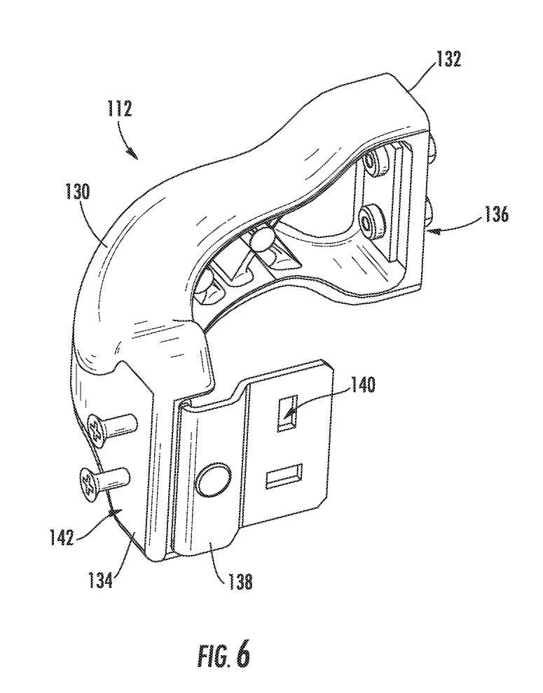

FIG. 6 is an orthogonal view of one of the offset brackets 112 of FIG. 5. The bracket 112 includes a frame attachment end 132 and an expansion attachment end 134 connected by a curved spine member 130. The expansion attachment end 134 is oriented at a 90 degree angle relative to the frame attachment end 132. The frame attachment end 132 includes a pair of apertures 136 disposed therethrough for attachment of the bracket 112 to the front frame 124 and rear frame 126 of the four post frame structure 110. The expansion attachment end 134 includes a side panel mounting element 138. The side panel mounting element 138, which is preferably a generally planar plate-like structure, is fixedly connected to the expansion attachment end 134 of the bracket 112 and includes a plurality of attachment apertures 140 for connection with side panels of the expansion kit. An additional pair of mounting holes 142 are disposed adjacent the expansion attachment end 134 of the bracket 112 and orthogonal to the side panel mounting element 138. Such holes 142 may be used to mount hinges, bumpers, a door strike, a latch point and the like.

In use, each offset bracket 112 may be mounted to the front- or rear-facing surface of a vertical member 114, as appropriate, such that it extends outwardly, away from the interior frame structure. Each offset bracket 112 may be attached to its respective vertical member 114 using the apertures 136 in the mounting surface located at the frame attachment end 132 of the bracket 112. Each offset bracket 112 is arranged so that its expansion attachment end 134 is oriented to point outwardly away from the side of the interior frame structure 110 as shown in FIG. 4. The idea is to avoid impeding any space created by the brackets 112 between sides of the frame structure 110 and side panels of the expansion kit. As illustrated, a first offset bracket 112 is disposed near the top of each vertical member 114 and a second offset bracket 112 is disposed near the bottom of each vertical member 114. Each lateral side of the interior frame structure 110 (front, left side, rear, right side) thus has four mounting points for mounting a respective panel.

The offset bracket 112 shown in FIG. 5 is an alternative embodiment of the offset bracket 12 shown in FIG. 2. Both serve to create space between a four post frame structure and panels of an expansion kit thereby forming an expanded equipment cabinet. It will be understood that although two mounting bracket embodiments 12,112 are shown herein, there are numerous additional mounting bracket embodiments that may be used to form an expanded equipment cabinet using a four post frame structure and panels of an expansion kit. Such additional embodiments although not explicitly shown herein are within the scope of the present invention.

As with the offset bracket 12 of FIG. 2, the offset brackets 112 provide versatility for a traditional frame structure 110 by providing a means to support various front, rear and side panels 102,104,106 away from the frame structure 110. Because the various panels 102,104,106 are thus located farther away from the equipment mounted in the interior of the frame structure 110 than panels mounted directly to the frame structure 110 would be, additional space is thus provided for cables, internal ducts, or other accessories. More particularly, the offset brackets 112 and center support bracket 113 adapt a conventional frame structure 110 to hold larger doors and side panels than could be accommodated by the interior frame structure 110 by itself, thereby increasing the area available for cable management and/or thermal management in the side space and front and back space of a data center cabinet while creating minimal impediment to cables entering through a raised floor tile or cabinet top panel.

In order to provide greater support for any of the panels 102,104,106, and particularly to provide a door stop for the free ends of a pair of doors such as a pair of doors comprising the rear panel 104 in the illustrated embodiment, a center support bracket 113 may be provided at the top or bottom of the front, rear, left or right side of the interior frame structure 110. As perhaps best illustrated in FIG. 5, such a center support bracket 113 may include two extension arms connected at their distal ends by a single cross arm. Each extension arm is attached to the lower rear cross member 118 using a respective mounting tab. Such a structure may be formed by bending or angling a single member along four lines to produce the extension arms, cross arm, and mounting tabs.

For a panel comprising a single door, such as the front door 102 illustrated herein, one of the offset brackets 112 may be modified by applying an additional door stop arm 144 thereto. As shown in FIG. 5, the door stop arm 144 includes an L-shaped arm mounted to the expansion attachment end 134 of the selected offset bracket 112. At the distal end of the L-shaped arm is a flange arranged to contact the bottom corner of the front door 102 when the door is swung closed against the rest of the cabinet 100. Although not illustrated, a door stop arm 144 may likewise be attached to the offset bracket 112 disposed at the upper corner of the front door 102 to provide similar functionality with regard to the top corner of the door 102.

The offset brackets 112 are mounted to the interior frame structure 110 using apertures 146 in the various members of the frame structure 110. If the interior frame structure 110 is to be produced in conjunction with the cabinet expansion kit, then the apertures 146 may be created in any desired location. However, in many cases, the cabinet expansion kit will be retrofitted to an existing interior frame structure 110. In this case, the offset brackets 112 may be installed in preexisting mounting apertures found in the vertical members 114 of most conventional interior frame structures 110. These apertures are often normally used to mount hinges and other support hardware for doors or other panels, or in some cases are used to support equipment in the frame structure 110. Typically, these apertures are located generally near a top and a bottom of the vertical members 114 so as to provide sufficient stability for the doors or other apparatuses mounted thereon while still providing ready access thereto.

The various components of the cabinet expansion kit may be connected to the interior frame structure 110 as follows. First, the offset brackets 112 may be mounted by connecting the frame attachment end 132 of each offset bracket 112 to a set of apertures 146 of the frame structure 110 using any known fasteners of suitable size and construction. As described previously, each offset bracket 112 is installed so that it extends outwardly from the front or rear of the interior frame structure 110, as appropriate, and so that the curved spine member 130 is oriented to extend outwardly from the respective side of the interior frame structure 110. In this arrangement, the mounting holes 142 in each offset bracket 112 are oriented to face in the same direction as the mounting apertures 146 to which the offset bracket 112 itself is mounted, but are shifted forward or rearward, as appropriate, and to the side, relative to the mounting apertures 146. In this sense, because the mounting holes 142 in the offset bracket 112 are often intended to serve the same purpose as the mounting apertures 146 (supporting panels, and particularly, providing an attachment point for a hinge used to support a door panel), the mounting holes 142 may be said to be “offset” from the original mounting apertures 146.

With the offset brackets 146 in place, displaced hinges, and therefore oversized front and rear door panels 102,104, may be attached to the mounting holes 142 of the offset brackets 112. Further, side panels may be attached to the side panel mounting elements 138 of the offset brackets 112. Any suitable mounting or attachment means may be used to provide these various connections. Optionally, additional mounting apertures 140 may be provided in the side panel mounting elements 138 or elsewhere in the offset bracket 112 in order to facilitate such connections.

As will be apparent to the Ordinary Artisan, flexibility is offered in a variety of ways, many of which were discussed previously with regard to the expanded electronic equipment cabinet 10 of FIGS. 1A-1E, 2 and 3. One additional variation is illustrated in FIGS. 4A and 4B, wherein the top panel extension 22 of the first embodiment is replaced with an alternative top panel extension 108 which is similar to the first top panel extension 22 but may not include cable openings therethrough.

In use, the expanded cabinet provides substantially more space for cables and cable routing apparatuses than were possible in the interior frame structure 110 by itself. With the cabinet expansion kit in place, cables may be routed outside the boundaries of the original frame structure in the space created by expanding the front, rear and sides of the cabinet. Conventional cable routing structures, such as raceways and the like, may be used to assist this process. As noted previously, in at least some embodiments, existing cable routing structures may be utilized, while in others, new cable routing structures may be developed.

Advantageously, use of the cabinet expansion kit permits a user to expand the volume of a frame structure 110 without having to replace the various members 114,116,118,120,122 of the frame structure 110, thus providing considerable cost savings. Expanding an existing frame structure 110, rather than replacing it, may also result in considerable labor savings, because electronic equipment mounted therein, and some or all of the cables connected to such equipment, may not need to be moved during the expansion process, and thus the frame structure 110 may be expanded without disturbing the installation therein.

As with the first embodiment, the offset brackets 112 and the various doors and other panels 102,104,106,108 may be dimensioned so as to form an expanded cabinet 100 that is the same in one or more dimensions as a larger frame structure (not shown). In other words, frame structures of different sizes could be provided such that installing a cabinet expansion kit on a smaller frame structure could produce an enclosure that is the same size as the larger frame structure. In conjunction with this approach, various doors and other panels 102,104,106,108 could be designed to mount either on the smaller frame structure 110, via the offset brackets 112, or on the larger frame structure (not shown) via direction connection. A product line built around this approach could provide even greater flexibility to users by offering multiple upgrade options to the user.

Also as with the first embodiment, further alternate cabinet configurations could allow for the space added by the offset brackets 112 to be asymmetrically biased. In other words, the additional volume created by the offset brackets 112 may be added more to the front or rear of the cabinet and/or more to one side of the cabinet or the other by adding offset brackets (not shown) with lengths, as appropriate. Such an embodiment would provide flexibility and customizability. For example, offset brackets 112 of varying lengths could be used in a situation wherein large cable access requirements are only present on the forward or rearward face of the equipment. Of course, to achieve such an arrangement, the same front, rear and side panels could be utilized, but different offset brackets and a different top panel or top panel extension may be required.

According to the foregoing teachings, an existing enclosure (not shown herein but illustrated in commonly-assigned U.S. Design Patent Application Serial No. 29,248,104, the entirety of which is incorporated herein by reference) may be converted to an expanded electronic equipment cabinet 10,100 by removing one or more of the front, left side, rear and right side panels, installing offset brackets as described herein, and mounting oversized front, left side, rear and right side panels thereon to create the expanded electronic equipment cabinet 10,100. By using different combinations of panels and offset brackets, original panels may be retained and reused, or replaced, as desired, and differently-sized expanded electronic equipment cabinets 10,100 may be formed, wherein additional space is enclosed within the second enclosure, between the panels and the frame structure, as compared to the space enclosed within the first enclosure.

Based on the foregoing description, it will be readily understood by those persons skilled in the art that the present invention is susceptible of broad utility and application. Many embodiments and adaptations of the present invention other than those specifically described herein, as well as many variations, modifications, and equivalent arrangements, will be apparent from or reasonably suggested by the present invention and the foregoing descriptions thereof, without departing from the substance or scope of the present invention.

Accordingly, while the present invention has been described herein in detail in relation to one or more preferred embodiments, it is to be understood that this disclosure is only illustrative and exemplary of the present invention and is made merely for the purpose of providing a full and enabling disclosure of the invention. The foregoing disclosure is not intended to be construed to limit the present invention or otherwise exclude any such other embodiments, adaptations, variations, modifications or equivalent arrangements, the present invention being limited only by the claims appended hereto and the equivalents thereof.

What is claimed is:

1. An expanded electronic equipment cabinet, comprising:
(a) a frame structure for supporting electronic equipment; and
(b) a cabinet expansion kit, including:
(i) a panel, and
(ii) a plurality of offset brackets;
(c) wherein a first end of each offset bracket of the plurality of offset brackets is connected to, and extends laterally from, the frame structure and wherein the panel is connected to a second end of each offset bracket of the plurality of offset brackets such that the panel is supported by the offset brackets at a laterally-displaced distance from, and at right angles to, the frame structure.

2. The expanded electronic equipment cabinet of claim 1, wherein the panel is a first panel and wherein the cabinet expansion kit further includes a second panel that is connected to the second end of each offset bracket of the plurality of offset brackets such that the second panel is supported by the offset brackets at a laterally-displaced distance from, and at right angles to, the frame structure.

3. The expanded electronic equipment cabinet of claim 2, wherein the first and second panels are a door and a side panel, respectively, that are arranged at right angles to each other.

4. The expanded electronic equipment cabinet of claim 1, wherein a space is created between the panel and the frame structure to accommodate accessories connected to the electronic equipment supported by the frame structure.

5. The expanded electronic equipment cabinet of claim 1, wherein each offset bracket includes a curved spine extending laterally away from the frame structure.

6. The expanded electronic equipment cabinet of claim 1, wherein each offset bracket includes first and second arms, each having proximal and distal ends and a rectilinear form, wherein the proximal end of the second arm is fixedly connected to the distal end of the first arm such that the second arm forms an angle relative to the first arm.

7. The expanded electronic equipment cabinet of claim 6, wherein the angle formed between the first and second arms is a right angle.

8. The expanded electronic equipment cabinet of claim 6, wherein the first and second arms are oriented at right angles to the frame structure.

9. The expanded electronic equipment cabinet of claim 1, wherein the frame structure includes at least four vertical members, each having at least two of the plurality of offset brackets attached thereto and extending laterally therefrom, and wherein the cabinet expansion kit includes at least four panels, each of which is supported at each of its four corners by an offset bracket.

10. The expanded electronic equipment cabinet of claim 9, wherein the at least four panels are each displaced an equal distance from the frame structure.

11. The expanded electronic equipment cabinet of claim 9, wherein a first of the at least four panels is a front panel, a second of the at least four panels is a rear panel, a third of the at least four panels is a left side panel, and a fourth of the at least four panels is a right side panel, wherein the front and rear panels are displaced a first distance from the frame structure and the left and right side panels are displaced a second distance from the frame structure, and wherein the first and second distances are unequal.

12. The expanded electronic equipment cabinet of claim 9, wherein each of the at least four panels has a respective width, wherein each of the at least four panels is adjacent a respective pair of vertical members, and wherein at least two of the at least four panels are oversized panels that are each wider than the distance between the two vertical members of the respective pair of vertical members to which the respective panel is adjacent.

13. The expanded electronic equipment cabinet of claim 12, wherein four of the at least four panels are oversized panels that are each wider than the distance between the two vertical members of the pair of vertical members to which the respective panel is adjacent.

14. The expanded electronic equipment cabinet of claim 1, further comprising a top panel extension that extends laterally and outwardly from a top of the frame structure by an amount equal to the laterally-displaced distance.

15. The expanded electronic equipment cabinet of claim 14, further comprising a top panel disposed on the top of the frame structure, wherein the top panel extension fits around the top panel.

16. The expanded electronic equipment cabinet of claim 14, wherein one or more cable openings are arranged in the top panel extension.

17. The expanded electronic equipment cabinet of claim 1, wherein the second end of each offset bracket includes a planar flange extending therefrom.

18. The expanded electronic equipment cabinet of claim 1, wherein:
(d) the first end has a first mounting element adapted to connect to the frame structure, the first mounting element including a first planar element, having at least one aperture penetrating therethrough, that is adapted to abut a planar surface of the frame structure; and
(e) the second end has a second mounting element for mounting the panel thereon such that the panel is supported at a laterally-displaced distance from the frame structure, wherein the second mounting element includes a second planar element, having at least one aperture penetrating therethrough, that is perpendicular to the first planar element.

19. A method of expanding an electronic equipment cabinet having a frame structure for supporting electronic equipment, comprising:
(a) providing a first enclosure for supporting electronic equipment, the first enclosure including at least one panel mounted on a frame structure formed from a plurality of frame members, including a plurality of vertical members;
(b) removing a first panel, of the at least one panel, from a face of the frame structure;
(c) attaching a plurality of offset brackets to vertical members of the frame structure, each offset bracket extending laterally from the frame structure and including a mounting element for supporting a panel; and
(d) attaching a second panel to the mounting element on the offset bracket, thereby creating a second enclosure formed from the frame structure and the second panel;
(e) wherein additional space is enclosed within the second enclosure, between the second panel and the frame structure, as compared to the space enclosed within the first enclosure.

20. The method of claim 19, wherein the first and second panels are the same width.

21. The method of claim 19, wherein the first and second panels are different panels and wherein the second panel is wider than the first panel.

22. The method of claim 19, wherein each offset bracket includes first and second arms, each having proximal and distal ends and a rectilinear form, wherein the proximal end of the second arm is fixedly connected to the distal end of the first arm such that the second arm forms a right angle relative to the first arm.

23. The method of claim 19, wherein each offset bracket includes a curved spine member.

24. A method of expanding an electronic equipment cabinet having a frame structure for supporting electronic equipment, comprising:
(a) providing a first enclosure for supporting electronic equipment, the first enclosure including a first front panel, a first left side panel, a first rear panel and a first right side panel, all mounted on a frame structure formed from a plurality of frame members, including four vertical post members;
(b) removing the first front, left side, rear and right side panels from the frame structure;
(c) attaching an offset bracket to each of the four vertical post members of the frame structure, each offset bracket extending laterally from the frame structure and including at least two mounting elements, each mounting element for supporting a panel;
(d) a second front panel to a mounting element on a first offset bracket, a second left side panel to a mounting element on the first offset bracket and to a mounting element on a second offset bracket, a second rear panel to a mounting element on the second offset bracket and to a mounting element on a third offset bracket, a second right side panel to a mounting element on the third offset bracket and to a mounting element on a fourth offset bracket, and the second front panel to a mounting element on the fourth offset bracket, thereby creating a second enclosure formed from the frame structure and the second front, left side, rear and right side panels;
(e) wherein additional space is enclosed within the second enclosure, between the second front, left side, rear and right side panels and the frame structure, as compared to the space enclosed within the first enclosure.

25. The method of claim 24, wherein each offset bracket includes first and second arms, each having proximal and distal ends and a rectilinear form, wherein the proximal end of the second arm is fixedly connected to the distal end of the first arm such that the second arm forms a right angle relative to the first arm.

26. The method of claim 24, wherein each offset bracket includes a curved spine member.
